(19) United States
(12) Patent Application Publication
(10) Pub. No.: US 2011/0031594 A1
(43) Pub. Date: Feb. 10, 2011

(54) CONDUCTOR PACKAGE STRUCTURE AND METHOD OF THE SAME

(75) Inventors: Diann-Fang Lin, Zhubei City (TW); Yu-Shan Hu, Yangmei Township (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 12/716,539

(22) Filed: Mar. 3, 2010

Related U.S. Application Data
(63) Continuation-in-part of application No. 12/536,546, filed on Aug. 6, 2009.

(51) Int. Cl. H01L 23/522; H01L 23/552

(52) U.S. Cl. 257/659; 257/700; 257/E23.142; 257/E23.114

(57) ABSTRACT

The present invention provides a conductor package structure that comprises a conductive base. An adhesive layer is formed on the conductive base. An electronic element is formed on the adhesive layer. Conductors form a signal connection between the surface of a filling material and the bottom of the filling material, wherein the filling material is filled in the space between the electronic element and the conductors.

### RELATED APPLICATIONS

The present application is a Continuation-in-Part (CIP) of U.S. application Ser. No. 12/536,546 filed Aug. 6, 2009 for “Conductor Package Structure and Method of the Same.”

### BACKGROUND OF THE INVENTION

1. Field of the Invention

This invention relates to a structure of package, and more particularly to a conductor package structure with signal channels.

2. Description of the Prior Art

In the field of semiconductor devices, the device density is increased and the device dimension is reduced, continuously. The demand for the packaging or interconnecting techniques in such high-density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of a chip package includes power distribution, signal distribution, heat dissipation, protection and support . . . and so on. As a semiconductor become more complicated, the traditional package technique, for example lead frame package, flex package, rigid package technique, cannot meet the demand of producing a smaller chip with high-density elements on the chip.

Typically, the semiconductor devices require protection from moisture and mechanical damage. The structure involves the technology of a package. In the technology, the semiconductor dies or chips are usually individually packaged in a plastic or ceramic package. The package is required to protect the die and spread the heat generated by the devices. Therefore, heat dissipation is very important in semiconductor devices, particularly as the power and the performance of the device increase.

Furthermore, conventional package technologies have to divide a dice on a wafer into respective dies and then package the die respectively. Therefore, these techniques are time consuming for the manufacturing process. The chip package technique is highly influenced by the development of integrated circuits. Therefore, as the size of electronics has become more demanding, so does the package technique. For the reasons mentioned above, the trend of the package technique today is toward ball grid array (BOA), flip chip (FC-BGA), chip scale package (CSP), and wafer level package (WLP). “Wafer level package” is to be understood as meaning that the entire packaging and all the interconnections on the wafer as well as other processing steps are carried out before the singulation (dicing) into chips (dice). Generally, after completion of all assembling processes or packaging processes, individual semiconductor packages are separated from a wafer having a plurality of semiconductor dies. The wafer level package has extremely small dimensions combined with extremely good electrical properties.

WLP technique is an advanced packaging technology, by which the die are manufactured and tested on the wafer, and then singulated by dicing for assembly in a surface-mount line. Because the wafer level package technique utilizes the whole wafer as one object, not utilizing a single chip or die. Therefore, before performing a scribing process, packaging and testing has been accomplished. Furthermore, WLP is such an advanced technique that the process of wire bonding, die mount and under-fill can be omitted. By utilizing WLP technique, the cost and manufacturing time can be reduced, and the resulting structure of WLP can be equal to the die. Therefore, this technique can meet the demands of miniaturization of electronic devices.

Although WLP technique has the advantages mentioned above, some issues still exist influencing the acceptance of WLP technique. For example, although utilizing WLP technique can reduce the CTE mismatch between IC and the interconnecting substrate, as the size of the device minimizes, the CTE difference between the materials of a structure of WLP becomes another critical factor to mechanical instability of the structure. Furthermore, in this wafer-level chip-scale package, a plurality of bond pads formed on the semiconductor die is redistributed through conventional redistribution processes involving a redistribution layer into a plurality of metal pads in an area array type. Solder balls are directly fused on the metal pads, which are formed in the area array type by means of the redistribution process. Typically, all of the stacked redistribution layers are formed over the built-up layer over the die. Therefore, the thickness of the package is increased. This may conflict with the demand of reducing the size of a chip.

Therefore, the present invention provides a conductor package structure to reduce the package thickness to overcome the aforementioned problem and also provide the better board level reliability test of temperature cycling.

### SUMMARY OF THE INVENTION

The present invention provides a conductor package structure comprising a base. An adhesive layer is formed on the base. At least one electronic element is formed on the adhesive layer. A plurality of conductors are forming a signal connection between the surface of a filling material and the bottom of the filling material, wherein the filling material is filled in the space between the plurality of conductors and around the electric element, and a re-distribution (RDL) layer formed over said electronic element and connecting between said electronic element and said connectors.

The base is formed between the conductors, and the bottom of the conductors and the bottom of the base are coplanar. A plurality of conductors includes at least one height. The base further comprises at least one through opening formed therein. The adhesive layer comprises conductive material. The filling material is adjacent to the sidewall of the electronic element and the base, and covering the active side of the electronic element. The conductor package structure further comprises a conductive layer formed between said electronic element and said adhesive layer. The conductor package structure further comprises a conductive material formed under the conductors and the base. The conductor package structure further comprises a re-distribution layer (RDL) formed over the electronic element and connecting between the electronic element and the connectors. The conductor package structure further comprises a dielectric layer formed under the re-distribution layer (RDL). The conductor package structure further comprises a protective layer formed over said dielectric layer. The conductor package structure further comprises a marking layer formed over said protective layer. The bottom of the conductors has a concave shape portion formed therein.

In one embodiment, the conductor package structure of the present invention further includes an Electromagnetic Interference (EMI) shielding layer forming over the bottom and/or sidewall of the conductor package structure. In another embodiment, the conductor package structure of the present invention further includes an antenna structure forming over the bottom of the conductor package structure.

It should be noted that the present invention provide a method for forming a conductor package structure. Firstly, the process includes providing a tooling with alignment mark formed thereon. Next, a laminate film is formed on the tooling. Subsequently, die pads of dice is aligned to the alignment mark. The dice are bonded onto the laminate film. Then, a first adhesive layer is formed over backside of the dice. Next, a panel substrate having predetermined die through holes and a plurality of openings passing through the panel substrate is provided, wherein the die through hole is to receive the die. The panel substrate is bonded onto backside of the dice. Then, an encapsulation material is filled into the die through holes and the plurality of openings. The laminate film is removed. Next, the panel substrate is bonded onto a carrier such that active region of the dice are upwardly, wherein the panel substrate includes base and conductor. A second adhesive layer is formed over the protective layer. Finally, a laser marking process based on said second adhesive layer is utilized to form a marking layer.

The method further comprises a step of forming a conductive layer between the electronic element and the adhesive layer. The method further comprises a step of forming a conductive material on the panel substrate for signal connection. The method further comprises a step of forming re-distribution layer (RDL) over the electronic element and the connectors, and thereby connecting between the pads of said electronic element and the connectors. The method further comprises a step of forming a dielectric layer over the panel substrate, the encapsulation material and the dice to expose the conductors and the die pads. The method further comprises a step of forming a protective layer to cover the re-distribution layer (RDL) and the dielectric layer for protection. The method further comprises a step of sawing the panel substrate along the scribe line to singulate and separate the package into individual units.

### BRIEF DESCRIPTION OF THE DRAWINGS

FIG. 1 illustrates a cross-sectional view of a basic conductor package structure in accordance with one embodiment of the present invention.

FIG. 2 illustrates a cross-sectional view of a downward conductor package structure with signal channels in accordance with one embodiment of the present invention.

FIG. 3 illustrates a cross-sectional view of a downward conductor package structure with signal channels in accordance with one embodiment of the present invention.

FIG. 4 illustrates a cross-sectional view of another downward conductor package structure with signal channels in accordance with one embodiment of the present invention.

FIG. 5 illustrates a cross-sectional view of another downward conductor package structure with signal channels in accordance with one embodiment of the present invention.

FIG. 6 illustrates a cross-sectional view of a dual-side conductor package structure with signal channels in accordance with one embodiment of the present invention.

FIG. 7 illustrates a cross-sectional view of a stacking conductor package structure with signal channels in accordance with one embodiment of the present invention.

FIG. 8 illustrates a cross-sectional view of a twin-side stacking conductor package structure with signal channels in accordance with one embodiment of the present invention.

FIG. 9 illustrates a cross-sectional view of an upward stacking conductor package structure with wire bond in accordance with one embodiment of the present invention.

FIG. 10 illustrates a cross-sectional view of an individual conductor package structure in accordance with one embodiment of the present invention.

### DESCRIPTION OF THE PREFERRED EMBODIMENT

The invention will now be described in greater detail with preferred embodiments of the invention and illustrations attached. Nevertheless, it should be recognized that the preferred embodiments of the invention are only for illustrating the present invention. Besides the preferred embodiment mentioned here, the present invention can be practiced in a wide range of other embodiments besides those explicitly described, and the scope of the present invention is expressly not limited except as specified in the accompanying claims.

The present invention discloses a conductor package structure utilizing a base having predetermined die through holes and a plurality of openings passing through the base. Signal channels are formed over an electronic element and via connectors, and thereby connecting between the electronic element and via connectors. A marking layer is formed over the signal channels.

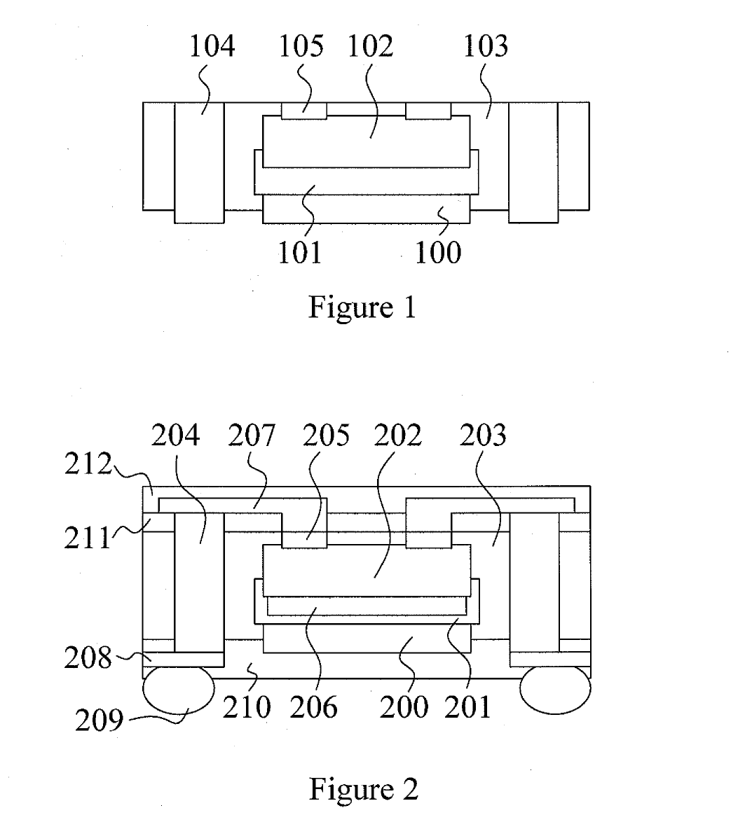

FIG. 1 illustrates a cross-sectional view of a basic conductor package structure in accordance with one embodiment of the present invention. As shown in the FIG. 1, the conductor package structure includes a substrate having predetermined die through holes and a plurality of openings passing through the substrate, wherein the die through hole is to receive a die 102 with die pads 105 formed thereon. In one embodiment, the substrate includes base 100 and conductors 104, wherein the base 100 are formed between the conductors 104, and the bottom of the conductors 104 and the bottom of the base 100 are coplanar. The material of the substrate includes alloy or metal. The alloy includes Alloy42 (42% Ni-58% Fe) or Kovar (29% Ni-17% Co-54% Fe). Preferably, the die 102 is an electronic element. The material of the base 100 includes alloy or metal. Pluralities of the plurality of openings are created through the base 100 from upper surface to lower surface of the base 100. An adhesive layer (material) 101 is formed over the base 100 for adhering the die 102. For example, the adhesive layer 101 comprises conductive material for electric conduction. Conductors 104 are formed between the surface of a filling material 103 passing through the filling material 103, wherein the conductors 104 comprises at least one material for signal connection (electrical communication). The filling material 103 is filled into the space (plurality of openings) between the electronic element 102 and the conductors 104. The filling material 103 is adjacent to the sidewall of the electronic element 102 and the base 100, and covering the active side of the electronic element 102. For example, the filling material 103 are surrounded by the base 100, electronic element 102 and the conductors 104.

FIG. 2 illustrates a cross-sectional view of a downward conductor package structure with re-distribution layer (RDL) in accordance with one embodiment of the present invention. As shown in the FIG. 2, the downward conductor package structure includes a substrate consisted of base 200 and conductors 204, wherein the base 200 are formed between the conductors 204 and the bottom of the conductors 204 and the bottom of the base 200 are coplanar, and a plurality of conductors includes at least one height. An adhesive layer (material) 201 is formed under the base 200 for adhering a die 202. Preferably, the die 202 is an electronic element. The electronic element may comprise a die, a chip, a chip size package or a packaged element. For example, the adhesive layer 201 comprises conductive material. Conductors 204 are formed between the surface of a filling material 203 passing through the filling material 203, wherein the conductors 204 comprises at least one material for signal connection (electrical communication). The filling material 203 is filled into the space between the electronic element 202 and the conductors 204. The filling material 203 is adjacent to the sidewall of the electronic element 202 and the base 200, and covering the active side of the electronic element 202. For example, the filling material 203 are surrounded by the base 200, electronic element 202 and the conductors 204. Contact pads (signal channels) 208 are located on the lower surface of the conductors 204 and connected to the conductors 204. A dielectric (buffer) layer 211 is formed over the electronic element 202 and the filling material 203, and under signal channels 207, to expose the conductors 204 and pads 205 of the electronic element 202. In one embodiment, the dielectric layer 211 comprises an elastic material, photosensitive material. Signal channels 207, for example redistribution layer (RDL), are formed over (upper surface of) the electronic element 202 and the connectors 204, and thereby connecting between the pads 205 of the electronic element 202 and via connectors 204. A conductive layer 206 is formed between the electronic element 202 and the adhesive layer 201 for electric conduction. A protective layer 210 is formed under the filling material 203 for protection and covering the filling material 203, the base 200, the conductors 204 and the signal channels 208 to expose the signal channels 208. Solder bumps/balls 209 are formed under the signal channels 208 for signal connection. Another protective layer 212 is formed over (upper surface of) the signal channels 207 for protection and covering the dielectric (buffer) layer 211 and the signal channels 207. In one embodiment, material of the protective layers 210, 212 comprises SINR, silicone rubber, and the protective layer 210 may be formed by molding or gluing method (dispensing or printing).

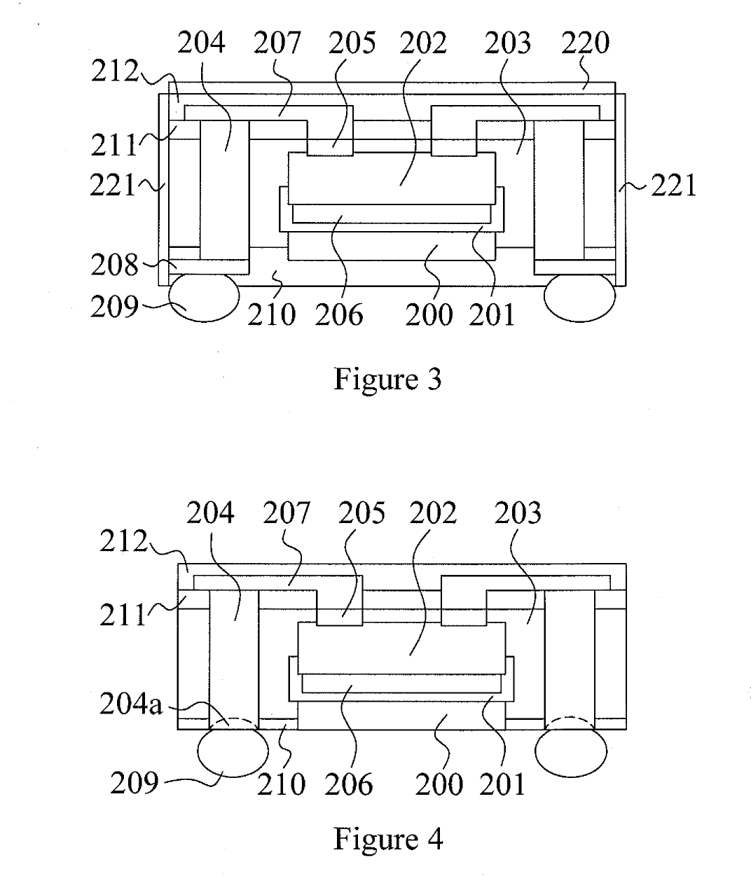

In one embodiment, the conductor package structure with re-distribution layer (RDL) of the present invention further includes an Electromagnetic Interference (EMI) shielding layer forming over the bottom and/or sidewall of the conductor package structure. For example, the Electromagnetic Interference (EMI) shielding layer 220, 221 may be formed over the protective layer 212 and/or sidewall of the conductor package structure, shown in FIG. 3. The EMI shielding layer 220, 221 may be formed by a conductive material, such as metal.

FIG. 4 illustrates a cross-sectional view of another downward conductor package structure with signal channels in accordance with one embodiment of the present invention. As shown in the FIG. 4, the downward conductor package structure omits signal channels 208. The protective layer 210 is formed under the filling material 203 for protection and covering the filling material 203 to expose the connectors 204 and the base 200. Solder bumps/balls 209 are formed under the connectors 204 for signal connection. Most of the parts of the FIG. 3 are similar to FIG. 2; and therefore the detailed descriptions are omitted. In such embodiment, the exposing base 200 can enhance the performance of heat dissipation. In one embodiment, especially, bottom of the conductors 204 has a concave shape portion 204a formed therein for facilitating aligning and receiving with the solder bumps/balls 209 such that the solder bumps/balls 209 may be accurately attached on the conductors 204. The concave shape portion 204a may be formed by a photolithography process and an etching process.

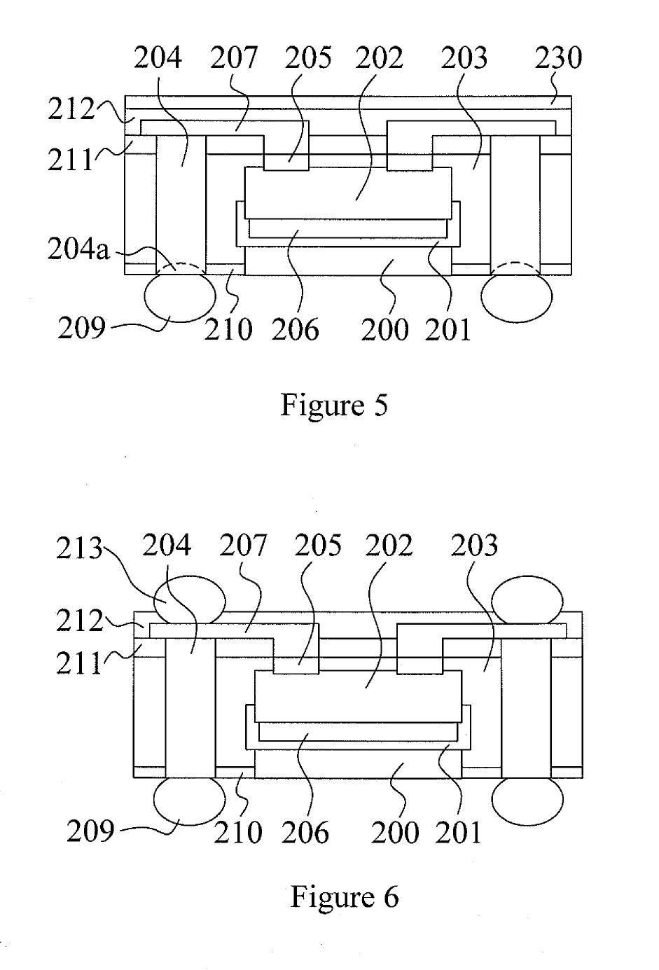

In another embodiment, the conductor package structure with re-distribution layer (RDL) of the present invention further includes an antenna structure forming over the bottom of the conductor package structure. For example, the antenna structure 230 may be formed over the protective layer 212, shown in FIG. 5.

FIG. 6 illustrates a cross-sectional view of a dual-side downward conductor package structure with signal channels in accordance with one embodiment of the present invention. As shown in the FIG. 6, the downward conductor package structure omits signal channels 208. The protective layer 210 is formed under the filling material 203 for protection and covering the filling material 203 to expose the connectors 204 and the base 200. Solder bumps/balls 209 are formed under the connectors 204 for signal connection. The protective layer 212 is formed over (upper surface of) the signal channels 207 for protection and covering the dielectric (buffer) layer 211 and the signal channels 207 to expose the signal channels 207. Solder bumps/balls 213 are formed over the signal channels 207 for signal connection. Most of the parts of the FIG. 6 are similar to FIG. 4; and therefore the detailed descriptions are omitted. In such embodiment, the exposing base 200 can enhance the performance of heat dissipation.

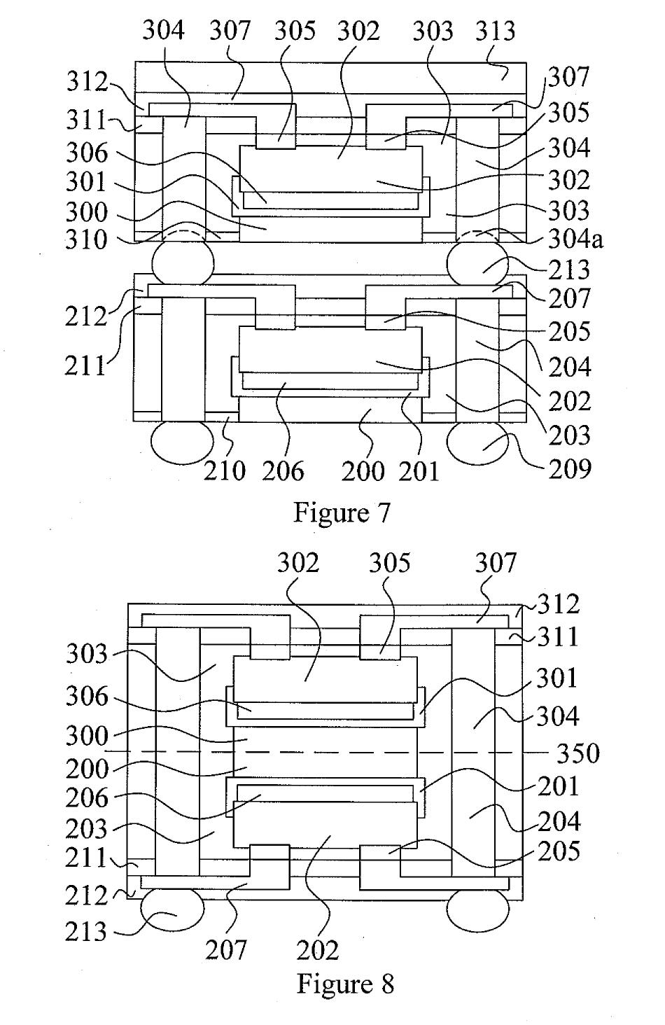

FIG. 7 illustrates a cross-sectional view of a stacking conductor package structure with signal channels in accordance with one embodiment of the present invention. As shown in the FIG. 7, it shows a stacking conductor package structure, which can be made by upper conductor package structure and lower dual-side downward conductor package structure. Solder bumps/balls of the upper conductor package structure may be omitted. Solder bumps/balls 213 of the lower dual-side downward conductor package structure may be formed between the signal channels 207 and conductors 304 for signal connection. In such embodiment, parts of the upper conductor package structure are similar to the FIG. 4, which includes a base 300, an adhesive layer 301, an electronic element 302 with pads 305, a filling material 303, conductors 304, a conductive layer 306, signal channels 307, a protective layer 310, a dielectric layer 311, a protective layer 312 and a marking layer 313. The description of the parts of the upper conductor package structure may be referred to the FIG. 2. The marking layer 313 is formed on the protective layers 312. In one embodiment, especially, bottom of the conductors 304 has a concave shape portion 304a formed therein for facilitating aligning and receiving with the solder bumps/balls 213 such that the solder bumps/balls 213 may be accurately attached on the conductors 304. The concave shape portion 304a may be formed by a photolithography process and an etching process.

FIG. 8 illustrates a cross-sectional view of a twin side stacking conductor package structure with signal channels in accordance with one embodiment of the present invention. As shown in the FIG. 8, it shows a twin side stacking conductor package structure which can be made by an upper active area upward conductor package structure and a lower active area downward conductor package structure. The upper conductor package structure and lower conductor package structure may be an identical package structure, wherein the base 200,300, the filling material 203,303 and the conductors 204,304 are configured with each other along a connection area 350. Solder bumps/balls of the upper conductor package structure may be omitted. Solder bumps/balls 213 of the twin side stacking conductor package structure may be connected to an external electrical component for signal connection. In such embodiment, parts of the upper and lower conductor package structure are similar to the FIG. 3, wherein the upper conductor package structure includes a base 300, an adhesive layer 301, an electronic element 302 with pads 305, a filling material 303, conductors 304, a conductive layer 306, signal channels 307, a dielectric layer 311 and a protective layer 312, and wherein the lower conductor package structure includes a base 200, an adhesive layer 201, an electronic element 202 with pads 205, a filling material 203, conductors 204, a conductive layer 206, signal channels 207, a dielectric layer 211, a protective layer 212 and solder bumps/balls 213. The detailed description of the parts of the upper and lower conductor package structure may be referred to the FIG. 2.

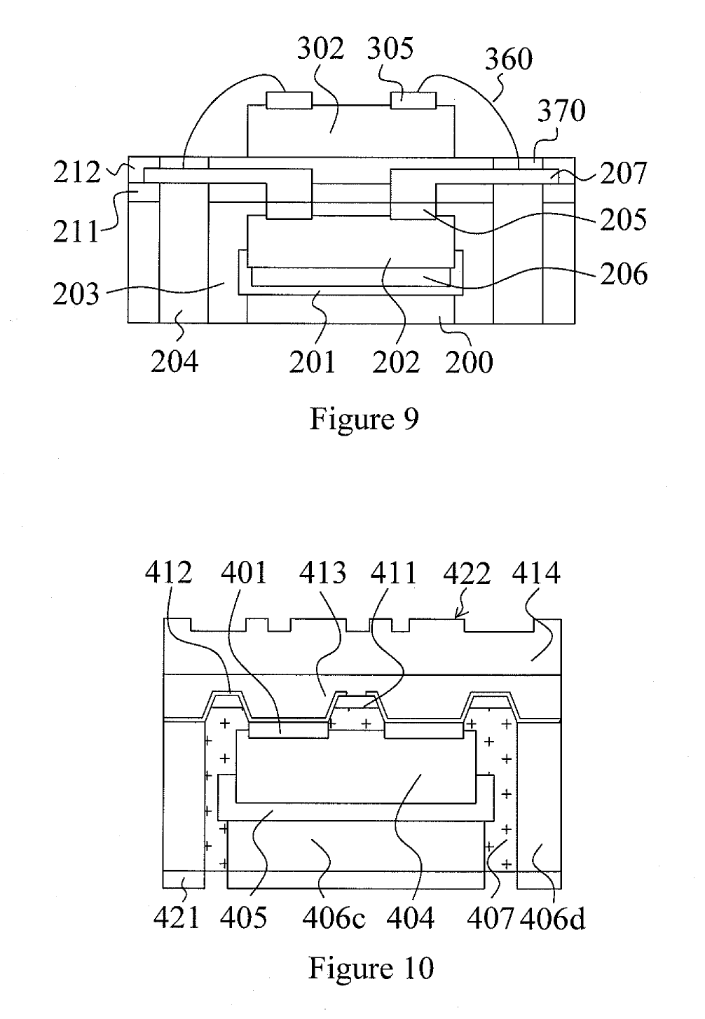

FIG. 9 illustrates a cross-sectional view of an upward stacking conductor package structure with signal channels in accordance with one embodiment of the present invention. As shown in the FIG. 9, it shows an upward stacking conductor package structure which can be made by an electronic element 302 located on a lower conductor package structure, for example located on the protective layer 212. Die pad 305 of the electronic element 302 is electrically connected to the signal channels 207 of the lower conductor package structure through a wire bonding 360. One terminal of the wire bonding 360 is located on the exposing area 370 of the protective layer 212 to connect the signal channels 207, and the other terminal of the wire bonding 360 is located on the die pad 305 for electrical connection. In such embodiment, parts of the lower conductor package structure are similar to the FIG. 4, wherein the lower conductor package structure includes a base, an adhesive layer 201, an electronic element 202 with pads 205, a filling material 203, conductors 204, a conductive layer 206, signal channels 207, a dielectric layer 211 and a protective layer 212. The detailed description of the parts of the lower conductor package structure may be referred to the FIG. 2.

FIG. 10 illustrates a cross section view of an individual conductor package structure in accordance with one embodiment of the present invention. An adhesive layer 405 is formed on a base 406c. At least one electronic element 404 is formed on the adhesive layer 405. A plurality of conductors 406d are formed signal connection between the surface of a filling material 407 and the bottom of said filling material, wherein the filling material 407 is filled in the space between the plurality of conductors 406d and around the electric element 404. The adhesive layer (conductive layer) 405 is located on backside of a die 404 at a predetermined thickness. The base 406c are formed between the conductors 406d, and the bottom of the conductors 406d and the bottom of the base 406c are coplanar. A dielectric layer 411, for example SINR material, is formed over the conductors 406d, the encapsulation (filling) material 407 and the die 404 to expose the conductors 406d and the die pads 401. Signal channels 412, for example redistribution layer (trace), are formed over (upper surface of) the electronic element 404 and the connectors 406d, and thereby connecting between the pads 401 of the electronic element 404 and via connectors 406d. A protective layer 413 is formed to cover the signal channels 412 and the dielectric layer 411 for protection, and an adhesive layer 414 is formed over the protective layer 413. A conductive material 421 is configured on the lower surface of the base 406c and the conductors 406d to solder joining an external object. The adhesive layer 414 is utilized by a laser marking process to form a marking surface 422.

It should be noted that the thickness of protective layer (film) is preferably around 0.1 um to 0.3 um and the reflection index close to the air reflection index 1. The materials of protective layer can be SiO2, Al2O3 or Fluoro-polymer etc.

The communication traces penetrate through the substrate via the contact through holes, and therefore the thickness of the die package is apparently shrinkage. The package of the present invention will be thinner than the prior art. Further, the substrate is pre-prepared before package. The die through hole and the contact through holes are pre-determined as well. Thus, the throughput will be improved.

Hence, the advantages of the present invention are:

The conductor substrate is pre-prepared with pre-form through hole; it can generates the super thin package due to die insert inside the substrate; it can be used as a stress buffer releasing area by filling silicone rubber to absorb the thermal stress due to the CTE difference between silicon die (CTE˜2.3) and the conductor substrate. The packaging throughput will be increased (manufacturing cycle time was reduced) due to applying the simple process. The reliability for both package and board level is better than ever, so no thermal mechanical stress can be applied on the solder bumps/balls. The cost is low and the process is simple. The manufacturing process can be applied as fully automatic, especially in module assembly. It is easy to form the combo package (dual dice package). It has a high yield rate due to particles free, simple process, and full automation.

Although preferred embodiments of the present invention have been described, it will be understood by those skilled in the art that the present invention should not be limited to the described preferred embodiments. Rather, various changes and modifications can be made within the spirit and scope of the present invention, as defined by the following claims.

Having described the invention, the following is claimed:

1. A conductor package structure, comprising:
a base;
an adhesive layer formed on said base;
at least one electronic element formed on said adhesive layer;
a plurality of conductors forming a signal connection between the surface of a filling material and the bottom of said filling material, wherein said filling material is filled in the space between said plurality of conductors and around said electric element; and
a re-distribution (RDL) layer formed over said electronic element and connecting between said electronic element and said connectors.

2. The structure of claim 1, wherein said base has at least one opening formed therein.

3. The structure of claim 1, wherein said base is formed between said conductors, and the bottom of said conductors and the bottom of said base are coplanar.

4. The structure of claim 1, wherein said adhesive layer comprises conductive material.

5. The structure of claim 1, wherein said filling material is adjacent to the side wall of said electronic element and said base, and cover the active side of said electronic element.

6. The structure of claim 1, wherein said filling material is exposed the top surface and the bottom surface of said conductors.

7. The structure of claim 1, further comprising a conductive layer formed between said electronic element and said adhesive layer.

8. The structure of claim 1, further comprising a conductive material formed under said conductors and said base.

9. The structure of claim 1, further comprising a dielectric layer formed under said re-distribution layer (RDL).

10. The structure of claim 9, further comprising a protective layer formed over said dielectric layer.

11. The structure of claim 10, further comprising a marking layer formed over said protective layer.

12. The structure of claim 10, wherein material of said protective layer includes silicone rubber, elastic material, photosensitive material or dielectric material.

13. The structure of claim 10, further comprising a second electronic element formed on said protective layer formed over said dielectric layer.

14. The structure of claim 13, wherein a die of said second electronic element is connected to said signal channels through a wire bonding.

15. The structure of claim 10, further comprising an Electromagnetic Interference shielding layer formed over bottom of said conductor package structure.

16. The structure of claim 10, further comprising an Electromagnetic Interference shielding layer formed over sidewall of said conductor package structure.

17. The structure of claim 10, further comprising an antenna structure formed over bottom of said conductor package structure.

18. The structure of claim 1, wherein the material of said base includes alloy or metal.

19. The structure of claim 1, wherein bottom of said conductors has a concave shape portion formed therein.

20. The structure of claim 1, wherein said electronic element comprises a die, a chip, a chip size package or a packaged element.
